(19) United States
(12) Patent Application Publication
(10) Pub. No.: US 2011/0030760 A1
(43) Pub. Date: Feb. 10, 2011

(54) PHOTOVOLTAIC DEVICE AND METHOD OF MANUFACTURING A PHOTOVOLTAIC DEVICE

(75) Inventors: Johannes Meier, Corcelles (CH); Ulrich Kroll, Corcelles (CH); Julien Bailat, Gloverier (CH)

Correspondence Address: PEARNE & GORDON LLP, 1801 EAST 9TH STREET, SUITE 1200, CLEVELAND, OH, 44114-3108, US

(73) Assignee: OERLIKON TRADING AG, TRUEBBACH, Truebbach (CH)

(21) Appl. No.: 12/988,004

(22) PCT Filed: Apr. 17, 2009
(86) PCT No.: PCT/EP09/54577

§ 371 Date: Oct. 15, 2010

Related U.S. Application Data
(60) Provisional application No. 61/046,103, filed on Apr. 18, 2008.
(60) Provisional application No. 61/093,418, filed on Sep. 1, 2008.

(51) Int. Cl. H01L 31/042; H01L 31/075; H01L 31/0368; H01L 31/18

(52) U.S. Cl. 136/244; 136/255; 438/96; 257/E31.047

(57) ABSTRACT

The photovoltaic device comprises a substrate, deposited on said substrate,
a first contact layer;
a second contact layer;
between said first and second contact layers:
   a first layer stack comprising a first p-doped layer, a first at least substantially intrinsic layer of amorphous hydrogenated silicon and a first n-doped layer;
   a second layer stack comprising a second p-doped layer, a second at least substantially intrinsic layer of microcrystalline hydrogenated silicon and a second n-doped layer. The thickness of the first at least substantially intrinsic layer is between 160 nm and 400 nm, and the thickness of the second at least substantially intrinsic layer is between 1 μm and 2 μm.

### TECHNICAL FIELD

The invention relates to the field of photovoltaic devices and their manufacture. More particularly, the invention relates to thin-film silicon-based solar cells and modules having the so-called tandem junction structure and to the improvement of the overall manufacturing process thereof.

### DEFINITIONS OF TERMS USED IN THE PRESENT PATENT APPLICATION

Hydrogenated Microcrystalline Silicon (μc-Si:H) (Also Called Nanocrystalline nc-Si:H) Material and Hydrogenated Amorphous Silicon (a-Si:H) Material
We understand in the present description and claims under hydrogenated microcrystalline silicon a material with at least 5 vol. % crystallinity (crystallites embedded in a more or less porous matrix of hydrogenated amorphous silicon). Microcrystalline grains have a diameter range perpendicular to their length extent of 5 nm to 100 nm.
Hydrogenated silicon material with less than the addressed 5 vol. % crystallinity is considered hydrogenated amorphous silicon.
Hydrogenated microcrystalline silicon involved in a photovoltaic device as i-layer material is characterized by an absolute external quantum efficiency at a wavelength of 800 nm and zero bias of at least 5%. Whereas hydrogenated amorphous silicon involved as addressed shows an absolute external quantum efficiency at a wavelength of 800 nm and zero bias below 5%.

### Intrinsic:

A layer or material is referred to as “intrinsic” if it is semiconducting with the Fermi-level located at least substantially in the middle between its valence band and the conduction band—i.e. midgap. No doping is voluntarily and/or involuntarily applied.

### Substantially Intrinsic:

Besides layers or materials defined above as “intrinsic”, the group of “substantially intrinsic” layers or materials additionally includes voluntarily and/or involuntarily compensated semiconducting layers or materials, i.e. layers and materials in which the Fermi-level is at least approximately midgap due to voluntary and/or involuntary doping.
   i-layer:
This term is used for addressing a substantially intrinsic layer.

### BACKGROUND OF THE INVENTION

Photovoltaic devices, also referred to as photoelectric conversion devices or more specifically as solar cells (when light originating from the sun shall be converted), are devices which convert light, especially sunlight, into direct current (DC) electrical power. For low-cost mass production, thin film solar cells are of particular interest.

The solar cell layer stack, i.e. the layer sequence responsible for or capable of the photovoltaic conversion is deposited as a sequence of thin layers. The deposition is customarily performed by a vacuum deposition process such as by PVD (physical vapour deposition), CVD (chemical vapour deposition), PECVD (plasma-enhanced chemical vapour deposition), LPCVD (low pressure CVD), Hot-Wire CVD, all or most of them being used in semiconductor technology.

A thin-film solar cell generally includes a first electrode (such as a contact layer), one or more semiconductor thin-film p-i-n or n-i-p stacks and a second electrode (such as another contact layer), which layers are successively stacked on a substrate. Each p-i-n or n-i-p stack includes an i-layer sandwiched between a p-doped layer and an n-doped layer. The i-layer occupies the major portion of the thickness of the thin-film p-i-n or n-i-p stack. Photoelectric conversion occurs primarily in the i-layer.

Prior Art FIG. 1 shows a photovoltaic cell 40 comprising a transparent substrate 41, e.g. of glass with a layer of a transparent conductive oxide (TCO) 42 deposited thereon. This layer is also called front contact “F/C” and acts as first electrode. The subsequent layer stack 43 comprises three layers, p-i-n. Layer 44 adjacent to TCO front contact 42 is positively-p-doped, the subsequent layer 45 is substantially intrinsic, and the following layer 46 is negatively-n-doped.

In an alternative embodiment, the layer sequence p-i-n as described can be inverted to n-i-p. This is done if light impinging direction on the stack is inverted. In this case the substrate 41 is intransparent and the contact layer 42 is reflecting. The layer 44 is then n-doped, layer 45 is at least substantially intrinsic, and layer 46 is p-doped.

The cell includes a second contact layer 47. In p-i-n configuration as shown in FIG. 1 layer 47 may be made e.g. of zinc oxide (ZnO), tin oxide (SnO₂) or ITO (Indium Tin Oxide) and is followed by a reflective layer 48.

In n-i-p configuration the second contact layer is transparent and no reflective layer 48 is provided.

For illustrative purposes, arrows indicate impinging light for p-i-n configuration, i.e. configuration where light impinges from substrate backside.

Depending on the material structure of the i-layer, a solar cell is called an amorphous hydrogenated silicon cell or a microcrystalline hydrogenated silicon cell independent of the material and material structure of the p- and n-doped layers.

Nowadays, so called tandem junction solar cells are of increasing interest. Tandem junction solar cells (also referred to as tandem cells) are cells with at least two thin-film single cells stacked one on the other. This way, cells with spectrally different conversion efficiencies can be combined to result in an overall spectral conversion efficiency which is effective in a broader spectral band compared with the spectral efficiency of each single cell. The single cell sensitivity spectra may be different from each other or mutually overlapping to some extent. Known in the art is the combination of an amorphous hydrogenated silicon cell with a microcrystalline hydrogenated silicon cell as latter is sensitive up to longer wavelengths of sunlight than the former one.

FIG. 2 shows such known tandem structure 50. In p-i-n configuration in analogy to that shown in FIG. 1 for a single cell, the tandem structure 50 comprises a substrate 41, a layer of transparent conductive oxide TCO 42 as first electrode, a p-i-n stack 43 of three layers 44, 45, 46 in analogy to the layer stack of the cell of FIG. 1, a rear contact layer 47 as the second electrode and a reflective layer 48. Properties and requirements are generally as described above for the cell of FIG. 1: The i-layer is of substantially intrinsic microcrystalline hydrogenated silicon.

Tandem cell 50 further comprises a second stack 51 of p-i-n layers 52, 53, 54, which are respectively p-doped, substantially intrinsic (i-type) and n-doped. The i-layer of the p-i-n stack 51 is of amorphous hydrogenated silicon.

In FIG. 2 the two stacks 51 and 43 are in p-i-n configuration for impinging light upon the backside of substrate 41.

If direction of impinging light is inversed, then the stacks are realised in n-i-p configuration and the sequence of the stacks 51 and 43 is inversed with respect to the now intransparent substrate.

It is an object of the present invention to provide for a tandem cell as was addressed and for a respective converter panel with an increased photovoltaic conversion efficiency and for a method for manufacturing such cell and panel.

### SUMMARY OF THE INVENTION

The addressed object is achieved by the device and method according to the claims.

The photovoltaic device comprises a substrate;
deposited upon the substrate:
a first contact layer;
a second contact layer;
between said first and second contact layers:
   a first layer stack comprising a first p-doped layer, a first at least substantially intrinsic layer of amorphous hydrogenated silicon and a first n-doped layer;
   a second layer stack comprising a second p-doped layer, a second at least substantially intrinsic layer of microcrystalline hydrogenated silicon and a second n-doped layer;
      wherein the thickness of the first at least substantially intrinsic layer is between 160 nm and 400 nm, and the thickness of the second at least substantially intrinsic layer is between 1 μm and 2 μm.

It has been found that this way, particularly high initial efficiencies and also particularly high stabilized efficiencies are achieved.

In one embodiment, the first contact layer is made substantially of TCO.

In one embodiment which may be combined with one or more of the before-addressed embodiments, the first at least substantially intrinsic layer is an intrinsic amorphous layer of hydrogenates silicon.

In one embodiment which may be combined with one or more of the before-addressed embodiments, the second at least substantially intrinsic layer is an intrinsic microcrystalline layer of hydrogenated silicon.

In one embodiment which may be combined with one or more of the before-addressed embodiments, the sequence of the layers is, along the direction of incident light:
first contact layer
first p-doped layer
first at least substantially intrinsic layer of amorphous hydrogenated silicon
first n-doped layer
second p-doped layer
second at least substantially intrinsic layer of microcrystalline hydrogenated silicon
second n-doped layer
second contact layer.

In one embodiment which may be combined with one or more of the before-addressed embodiments, the sum of the thicknesses of the first at least substantially intrinsic layer and of the second at least substantially intrinsic layer is below 2 μm.

In one embodiment which may be combined with one or more of the before-addressed embodiments, the second contact layer comprises, in particular substantially consists of TCO. In particular this TCO is of ZnO which may also be valid for the TCO applied as the first contact layer.

In one embodiment which may be combined with one or more of the before-addressed embodiments, the thickness of the first at least substantially intrinsic layer is 250 nm or 230 nm.

In one embodiment which may be combined with one or more of the before-addressed embodiments, the thickness of the second at least substantially intrinsic layer is 1.28 μm.

In one embodiment, the substrate is a commercially available possibly TCO- pre-coated glass, and the thickness of the first at least substantially intrinsic layer is 210 nm, the thickness of the second at least substantially intrinsic layer 1.41 μm.

In one embodiment which may be combined with one or more of the before-addressed embodiments, the substrate is a transparent substrate, in particular a glass substrate.

In one embodiment which may be combined with one or more of the before-addressed embodiments, the first and second layer stacks are deposited by means of PECVD.

The photovoltaic converter panel comprises at least one photovoltaic cell according to the invention, in particular a multitude thereof.

In one embodiment, the photovoltaic converter panel has a surface extent of at least 2500 cm², more particularly a surface extent of at least 1.4 m².

The method of manufacturing a photovoltaic device comprises the steps of
providing a substrate on which a first contact layer is deposited;
depositing in a predetermined sequence:
   a first layer stack by depositing a first p-doped layer, a first at least substantially intrinsic layer of amorphous hydrogenated silicon and a first n-doped layer;
   a second layer stack by depositing a second p-doped layer, a second at least substantially intrinsic layer of microcrystalline hydrogenated silicon and a second n-doped layer;
depositing a second contact layer;
   wherein depositing is carried out such that the thickness of the first at least substantially intrinsic layer results to be between 160 nm and 400 nm, and the thickness of the second at least substantially intrinsic layer results to be between 1 μm and 2 μm.

In one embodiment of the method, the method comprises the step of depositing or providing a TCO layer on the substrate e.g. by depositing or providing a layer of ZnO.

In one embodiment, the deposition is carried out so that the thickness of the first at least substantially intrinsic layer is 250 nm and the thickness of the second at least substantially intrinsic layer 1.28 μm.

Further embodiments and advantages of the invention become evident to the skilled artisan from the dependent claims and the following description of examples.

### BRIEF DESCRIPTION OF THE DRAWINGS

Below, the invention is described in more detail by means of examples and figures. The figures show:

FIG. 1 a schematic cross-section through a state-of-the-art single-junction photovoltaic device or solar cell;

FIG. 2 a schematic cross-section through a tandem-junction photovoltaic device or a tandem solar cell according to the invention;

FIG. 3 V-I-diagram of an a-Si:H/μc-Si:H tandem solar cell incorporating the invention.

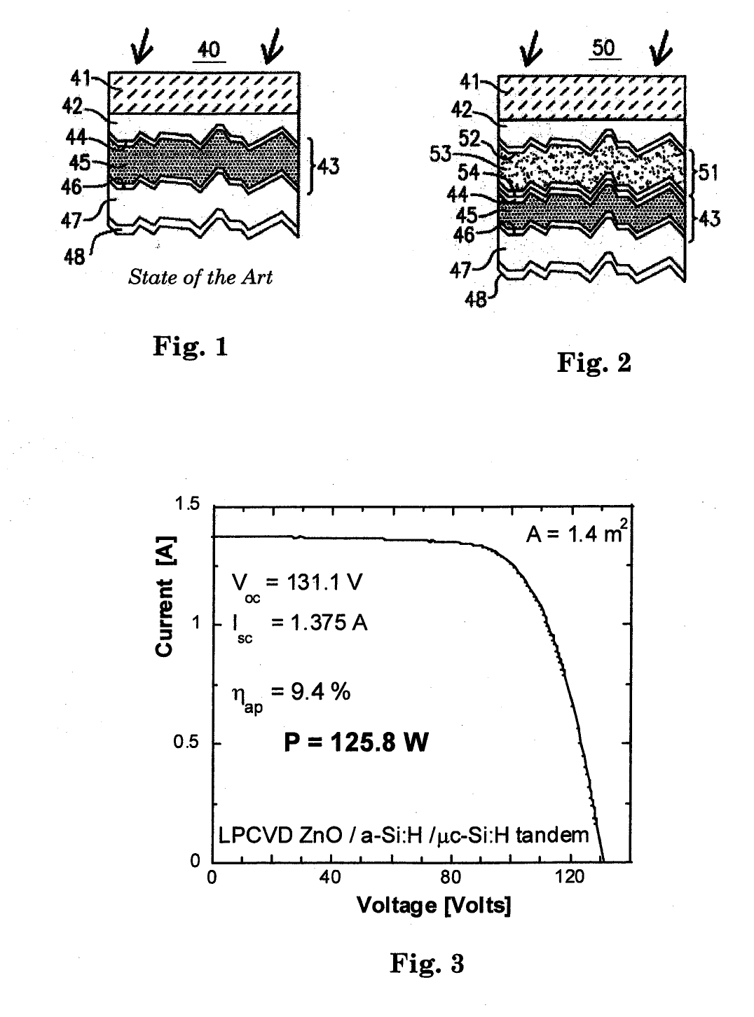

The described embodiments are meant as examples and shall not confine the invention.

### DETAILED DESCRIPTION OF THE INVENTION

The present invention relates to thin-film photovoltaic devices especially solar cell panels and to a method for their manufacturing. Although applicable to other photovoltaic devices we will now refer to solar cells. Solar cell panels can, for example, be used in architectural applications. We have described solar cell tandem structures in context with FIG. 2. Such structures combine commonly an a-Si:H and a μc-Si:H solar cell, i.e. a p-i-n or n-i-p stack including an i-layer of amorphous hydrogenated silicon and, respectively, a p-i-n or n-i-p stack including an i-layer of microcrystalline hydrogenated silicon.

As perfectly known to the skilled artisan, in a solar cell thin film semiconductor cell an i-layer is sandwiched between a p- and an n-doped layer.

The substrate used for solar cell panels can be of any suitable material for receiving the electrically conductive contact and the subsequent layer stacks. The substrate is generally flat and can be glass, glass-ceramics, ceramics or other glass-like material, a plastic such as a polyimide, or a metal film such as a film of aluminum, steel, titanium, chromium, iron, and the like. In order to meet the goal of efficient production of solar cell panels, standardization is desirable. One size common in the market today is based on a 1.4 m2 glass substrate with 1.1 m×1.3 m extent. The present invention, however, is not limited to this size and may be successfully applied to other sizes and shapes, be it rectangular or square.

The manufacturing process described herein results in a tandem cell structure of high conversion efficiency, η.

Following the structure as shown in FIG. 2, on a glass substrate 41, a TCO layer 42 made of ZnO has been deposited. Subsequently a p-i-n stack 51 with an intrinsic, amorphous layer of hydrogenated silicon was deposited, then a p-i-n stack 43 with an intrinsic, microcrystalline layer of hydrogenated silicon. Then a further TCO layer was applied as back contact 47. The intrinsic layer of amorphous hydrogenated silicon had a thickness of 250 nm, the intrinsic layer of microcrystalline hydrogenated silicon a thickness of 1.28 μm. The initial efficiency of the tandem cell was ηᵢ=11.16% and the stabilised efficiency ηₛₜ=9.5%.

When a commercially available TCO- pre-coated glass was used an initial efficiency of ηᵢ=11.6% could be reached. In this case, the thickness of the intrinsic layer of amorphous hydrogenated silicon was 210 nm and the thickness of the intrinsic microcrystalline layer of hydrogenated silicon 1.41 μm.

The deposition process for the layer stacks 51 and 43 was performed using a KAI PECVD deposition system, as commercially available from Oerlikon Solar. The ZnO (TCO) layers were deposited on a system TCO 1200, also from Oerlikon Solar.

Further tandem solar cells with amorphous and with microcrystalline cells—called micromorph tandems—have been prepared in the KAI-M reactor, which showed initial efficiencies of 12.1%. Up-scaling of such micromorph tandems to mini-modules and to 1.4 m² area modules have led to remarkable high efficiencies.

Table I summarizes the AM1.5 I-V results of a-Si:H/μc-Si:H tandems cells of 1 cm² area with Asahi SnO₂ and LPCVD deposited ZnO, respectively, as front TCOs (cf. ref. 42 in FIG. 2). With Asahi SnO₂, we achieved a remarkable 12.1% initial cell efficiency, and with ZnO 11.8%.

TABLE I
AM1.5 I-V solar cell initial characteristics
of micromorph tandem cells achieved with LPCVD
deposited ZnO and Asahi SnO₂, respectively.

| Cell run | V_{oc} (V) | J_{sc} (mA/cm²) | η |
|---|---|---|---|
| Asahi SnO₂: | | | |
| #2065 | 1.363 | 12.13 | 12.13 |
| #2072 | 1.345 | 12.27 | 12.11 |
| LPCVD ZnO: | | | |
| #2024 | 1.332 | 12.21 | 11.81 |
| #2149 | 1.389 | 11.42 | 11.84 |

V_{oc}: open circuit voltage;
J_{sc}: short circuit current density.

One module of 1.4 m² achieved an initial power of 125.8 W (see FIG. 3). Since this module could be obtained with a rather thin intrinsic layer of microcrystalline hydrogenated silicon with a thickness of 230 nm, a stabilized module power of around 110 W is expected. The overall thickness of the intrinsic layers is below 2 μm.

What is claimed is:

1-11. (canceled)

12. A photovoltaic device comprising a substrate;
deposited upon said substrate:
a first contact layer;
a second contact layer;
between said first and second contact layers:
a first layer stack comprising a first p-doped layer, a first at least substantially intrinsic layer of amorphous hydrogenated silicon and a first n-doped layer;
a second layer stack comprising a second p-doped layer, a second at least substantially intrinsic layer of microcrystalline hydrogenated silicon and a second n-doped layer;
wherein the thickness of said first at least substantially intrinsic layer is 210 nm, and the thickness of said second at least substantially intrinsic layer is 1.41 μm.

13. The photovoltaic device according to claim 12, wherein, as said substrate, a commercially available TCO-pre-coated glass is used.

14. The photovoltaic device according to claim 12, wherein said substrate is a glass substrate.

15. The photovoltaic device according to claim 12, wherein said first and second layer stacks are deposited by means of PECVD.

16. A photovoltaic converter panel comprising at least one photovoltaic cell according to claim 12.

17. The photovoltaic converter panel according to claim 16, having a surface extent of at least 2500 cm².

18. Method of manufacturing a photovoltaic device, said method comprising the steps of
providing a substrate on which a first contact layer is deposited;
depositing thereon in a predetermined sequence:
a first layer stack by depositing a first p-doped layer, a first at least substantially intrinsic layer of amorphous hydrogenated silicon and a first n-doped layer;
a second layer stack by depositing a second p-doped layer, a second at least substantially intrinsic layer of microcrystalline hydrogenated silicon and a second n-doped layer;
depositing a second contact layer;
wherein depositing is carried out such that the thickness of said first at least substantially intrinsic layer results to be 210 nm, and the thickness of said second at least substantially intrinsic layer results to be 1.41 μm.

19. The method according to claim 18, wherein, as said substrate, a commercially available TCO-pre-coated glass is used.
